(19) United States
(12) Patent Application Publication
(10) Pub. No.: US 2026/0182078 A1
(43) Pub. Date: Jun. 25, 2026

(54) FLIP-CHIP PHOTODIODE INTEGRATED STRUCTURE AND MANUFACTURING METHOD THEREOF

(71) Applicant: Taiwan-Asia Semiconductor Corporation, Hsinchu City (TW)

(72) Inventor: Ming-Hung Wei, Hsinchu City (TW)

(21) Appl. No.: 19/360,265

(22) Filed: Oct. 16, 2025

(30) Foreign Application Priority Data
Dec. 24, 2024 (TW) 113150524

(51) Int. Cl. H10F 77/20; H10F 39/10

(52) U.S. Cl. CPC H10F 77/206; H10F 39/107

(57) ABSTRACT

This invention provides a flip-chip photodiode integrated structure, including a first flip-chip photodiode unit, a second flip-chip photodiode unit, a first common electrode and a second common electrode. The first flip-chip photodiode unit includes a first substrate. The second flip-chip photodiode unit includes a second substrate. The second flip-chip photodiode unit is disposed adjacent to the first flip-chip photodiode unit, so that a first mounting surface of the first substrate and a second mounting surface of the second substrate are coplanar. The first common electrode is disposed at least on the first mounting surface, and the second common electrode is disposed at least on the second mounting surface. The first flip-chip photodiode unit and the second flip-chip photodiode unit are allowed to operate independently and simultaneously by electrically conducting the first common electrode and the second common electrode.

### CROSS REFERENCE TO RELATED APPLICATION

This application claims the benefit of Taiwan Patent Application Serial No. 113150524 filed on Dec. 24, 2024. The entirety of each application is incorporated herein by reference.

### BACKGROUND OF THE INVENTION

### 1. Field of the Invention

The present invention relates to a flip-chip photodiode integrated structure and a manufacturing method thereof, and more particularly, to a flip-chip photodiode integrated structure comprising a plurality of flip-chip photodiode units of different types and/or characteristics, and to a manufacturing method thereof.

### 2. Description of Related Art

In packaging and wire bonding process of conventional photodiode chips, gold wires must be drawn bonding from packaging substrates to metal electrodes in order to establishing electrical connections. However, this way also increases overall packaging areas of the photodiode chips and raises transmission distances and losses of current signals. If multiple photodiode chips are to be integrated, the problems caused by the aforementioned way of wire bonding will be magnified. It not only makes entire processes too complicated and manufacturing costs enhanced, but also influences overall packaging areas of the integrated photodiode chips.

In light of this, it is really worthy of research and development to design a flip-chip photodiode integrated structure and a manufacturing method thereof for solving those above-mentioned problems.

### SUMMARY OF THE INVENTION

An objective of the present invention is to provide a flip-chip photodiode integrated structure having a plurality of flip-chip photodiode units of different types/characteristics.

To achieve the above objective, the flip-chip photodiode integrated structure of the present invention comprises a first flip-chip photodiode unit, a second flip-chip photodiode unit, a first common electrode and a second common electrode. The first flip-chip photodiode unit includes a first substrate, and the first substrate has a first mounting surface and a first light-receiving surface opposite each other. The second flip-chip photodiode unit includes a second substrate, and the second substrate has a second mounting surface and a second light-receiving surface opposite each other. Wherein the second flip-chip photodiode unit is disposed adjacent to the first flip-chip photodiode unit and the first mounting surface is coplanar with the second mounting surface. The first common electrode is disposed at least on the first mounting surface and the second common electrode is disposed at least on the second mounting surface. Wherein the first flip-chip photodiode unit and the second flip-chip photodiode unit are allowed to operate independently and simultaneously by electrically conducting the first common electrode and the second common electrode.

In one embodiment of the present invention, the first common electrode extends from the first mounting surface to the second mounting surface, so as to contact the first substrate and the second substrate concurrently, and the second common electrode extends from the second mounting surface to the first mounting surface, so as to contact the first substrate and the second substrate concurrently.

In one embodiment of the present invention, the flip-chip photodiode integrated structure further comprises a metal connecting member. The metal connecting member extends from the first mounting surface to the second mounting surface, so as to contact the first substrate and the second substrate concurrently.

In one embodiment of the present invention, the metal connecting member includes a first end and a second end, wherein the first end is disposed on the first mounting surface and located at one side opposite to the first common electrode, to receive current from the first common electrode and flowing through the first substrate, and wherein the second end is disposed on the second mounting surface and located at one side opposite to the second common electrode, to let the current from the first end flow to the second common electrode through the second substrate.

In one embodiment of the present invention, the first flip-chip photodiode unit and the second flip-chip photodiode unit are flip-chip photodiode units having different characteristics respectively.

In one embodiment of the present invention, at least one difference existed between the first flip-chip photodiode unit and the second flip-chip photodiode unit, is selected from the group consisting of substrate materials, substrate thicknesses, substrate areas, substrate doping concentrations, substrate doping depths, light-receiving surface coating materials, light-receiving surface coating thicknesses, light-receiving surface coating areas and common electrode materials.

In one embodiment of the present invention, the flip-chip photodiode integrated structure further comprises a third flip-chip photodiode unit. The third flip-chip photodiode unit includes a third substrate, and the third substrate has a third mounting surface and a third light-receiving surface opposite each other. Wherein the third flip-chip photodiode unit is disposed adjacent to the first flip-chip photodiode unit or the second flip-chip photodiode unit, and the first mounting surface, the second mounting surface and the third mounting surface are coplanar. Wherein the first common electrode extends from the first mounting surface to the second mounting surface and to the third mounting surface, so that the first common electrode contacts the first substrate, the second substrate and the third substrate concurrently. While the second common electrode extends from the second mounting surface to the first mounting surface and to the third mounting surface, so that the second common electrode contacts the first substrate, the second substrate and the third substrate concurrently. And the first flip-chip photodiode unit, the second flip-chip photodiode unit and the third flip-chip photodiode unit are allowed to operate independently and simultaneously by electrically conducting the first common electrode and the second common electrode.

In one embodiment of the present invention, the flip-chip photodiode integrated structure further comprises a third flip-chip photodiode unit, a metal connecting member and a third common electrode. The third flip-chip photodiode unit includes a third substrate, and the third substrate has a third mounting surface and a third light-receiving surface opposite each other. Wherein the third flip-chip photodiode unit is disposed adjacent to the first flip-chip photodiode unit and/or the second flip-chip photodiode unit, and the first mounting surface, the second mounting surface and the third mounting surface are coplanar. The metal connecting member extends from the first mounting surface to the second mounting surface, so as to contact the first substrate and the second substrate concurrently. The third common electrode is disposed at least on the third mounting surface. And the first flip-chip photodiode unit, the second flip-chip photodiode unit and the third flip-chip photodiode unit are allowed to operate independently and simultaneously by electrically conducting the first common electrode, the second common electrode and the third common electrode.

In one embodiment of the present invention, the second common electrode extends from the second mounting surface to the third mounting surface, so as to contact the second substrate and the third substrate concurrently.

The present invention further provides a manufacturing method of a flip-chip photodiode integrated structure comprising following steps: providing a first flip-chip photodiode unit and a second flip-chip photodiode unit, wherein the first flip-chip photodiode unit includes a first substrate, and the first substrate has a first mounting surface and a first light-receiving surface opposite each other, and wherein the second flip-chip photodiode unit includes a second substrate, and the second substrate has a second mounting surface and a second light-receiving surface opposite each other; disposing the second flip-chip photodiode unit adjacent to the first flip-chip photodiode unit, wherein the first mounting surface and the second mounting surface are coplanar; disposing a first common electrode at least on the first mounting surface; and disposing a second common electrode at least on the second mounting surface. Wherein the first flip-chip photodiode unit and the second flip-chip photodiode unit are allowed to operate independently and simultaneously by electrically conducting the first common electrode and the second common electrode.

In one embodiment of the present invention, the first common electrode extends from the first mounting surface to the second mounting surface, so as to contact the first substrate and the second substrate concurrently, and the second common electrode extends from the second mounting surface to the first mounting surface, so as to contact the first substrate and the second substrate concurrently.

In one embodiment of the present invention, the manufacturing method of the flip-chip photodiode integrated structure further comprises following step: disposing a metal connecting member on the first mounting surface and the second mounting surface, wherein the metal connecting member extends from the first mounting surface to the second mounting surface, so as to contact the first substrate and the second substrate concurrently.

### BRIEF DESCRIPTION OF THE DRAWINGS

FIG. 1 is a perspective view of a flip-chip photodiode integrated structure of a first embodiment according to the present invention;

FIG. 2 is another perspective view of the flip-chip photodiode integrated structure of the first embodiment according to the present invention;

FIG. 3 is a perspective view of a flip-chip photodiode integrated structure of a second embodiment according to the present invention;

FIG. 4 is another perspective view of the flip-chip photodiode integrated structure of the second embodiment according to the present invention;

FIG. 5 is a perspective view of a flip-chip photodiode integrated structure of a third embodiment according to the present invention;

FIG. 6 is another perspective view of the flip-chip photodiode integrated structure of the third embodiment according to the present invention;

FIG. 7 is a perspective view of a flip-chip photodiode integrated structure of a fourth embodiment according to the present invention;

FIG. 8 is another perspective view of the flip-chip photodiode integrated structure of the fourth embodiment according to the present invention;

FIG. 9 is a flowchart of a manufacturing method of the flip-chip photodiode integrated structure according to the present invention;

FIG. 10 is a flowchart of the manufacturing method of another embodiment of the flip-chip photodiode integrated structure according to the present invention.

### DETAILED DESCRIPTION OF THE PREFERRED EMBODIMENT

Since various examples and embodiments in the present invention are only illustrative and non-restrictive, a person skilled in the art can easily conceive other examples and embodiments without contravening the scope of the present invention, after reading this specification, and can make the features and advantages of these embodiments more evident based on the following detailed description and claims.

Herein, the description of unit, element and component in the present invention uses “one”, “a”, or “an”. This is for convenience and for offering general meaning of the category of the present invention. Therefore, the description should be understood as including “one”, “at least one”, and singular and plural forms at the same time unless the context clearly indicates otherwise.

Herein, the description of the terms “first” or “second” and similar ordinal numbers are mainly used to distinguish or refer to the same or similar elements or structures and do not necessarily imply that such components or structures are spatially or temporally distinct order. It should be understood that ordinal numbers, in certain situations or configurations, may be used interchangeably without affecting the implementation of the present invention.

Herein, the description of “comprise”, “have” or other similar semantics have the non-exclusive meaning. For example, components or structures with a plurality of elements are not only limited to those disclosed in this specification, but also include generally inherent elements, which are not explicitly listed here for the components or the structures.

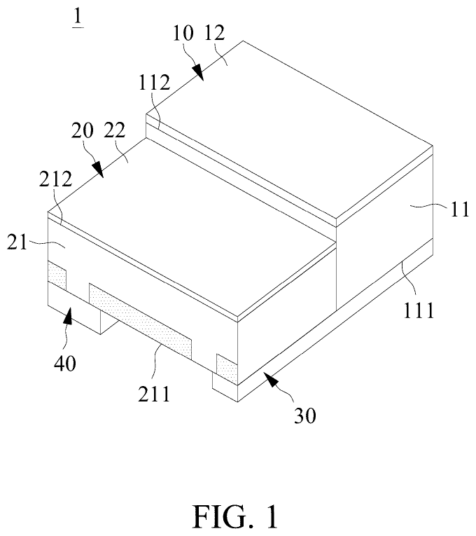

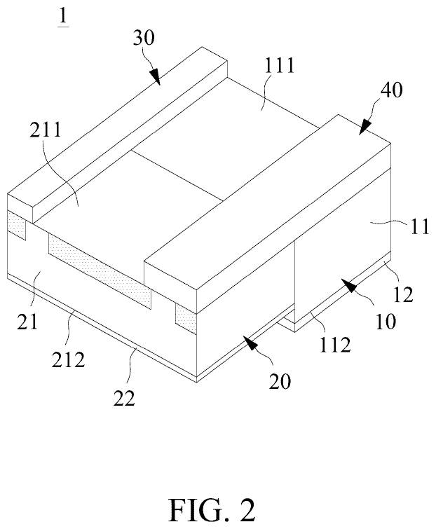

Please refer to FIG. 1 and FIG. 2 together. Wherein FIG. 1 is a perspective view of a flip-chip photodiode integrated structure of a first embodiment according to the present invention, and FIG. 2 is another perspective view of the flip-chip photodiode integrated structure of the first embodiment according to the present invention. As shown in FIG. 1 and FIG. 2, a flip-chip photodiode integrated structure 1 of the present invention at least comprises a first flip-chip photodiode unit 10, a second flip-chip photodiode unit 20, a first common electrode 30 and a second common electrode 40. The first flip-chip photodiode unit 10 and the second flip-chip photodiode unit 20 are independent flip-chip photodiode units, each configured to perform respective functions. The first common electrode 30 and the second common electrode 40 are electrodes shared by the first flip-chip photodiode unit 10 and the second flip-chip photodiode unit 20.

The first flip-chip photodiode unit 10 includes a first substrate 11 and a first coating layer 12. The first substrate 11 is a fundamental structure component of the first flip-chip photodiode unit 10, and is mainly formed by semiconductor materials through epitaxial processing, and different doping regions (such as P-type or N-type doping regions, shown as dotted regions in the figures) can be formed in the first substrate 11. According to different design and functional requirements of the first flip-chip photodiode unit 10, the material, a thickness, an area, a doping concentration and a doping depth of the first substrate 11 can be varied correspondingly. The first substrate 11 has a first mounting surface 111 and a first light-receiving surface 112 opposite each other. The first mounting surface 111 is configured for disposing corresponding electrodes or current guiding structures, and the first light-receiving surface 112 is configured to receive external light for performing photoelectric conversion of the first substrate 11.

The first coating layer 12 is disposed on the first light-receiving surface 112 of the first substrate 11, and the first coating layer 12 is applied to filter the external light received by the first light-receiving surface 112. According to the design and functional requirements of the first flip-chip photodiode unit 10, a material, a thickness and an area of the first coating layer 12 can be varied correspondingly.

The second flip-chip photodiode unit 20 includes a second substrate 21 and a second coating layer 22. The second substrate 21 is a fundamental structure component of the second flip-chip photodiode unit 20, and is mainly formed by semiconductor materials through epitaxial processing. According to different design and functional requirements of the second flip-chip photodiode unit 20, the material, a thickness, an area, a doping concentration and a doping depth of the second substrate 21 can be varied correspondingly. The second substrate 21 has a second mounting surface 211 and a second light-receiving surface 212 opposite each other. The second mounting surface 211 is configured for disposing corresponding electrodes or current guiding structures, and the second light-receiving surface 212 is configured to receive external light for performing photoelectric conversion of the second substrate 21.

The second coating layer 22 is disposed on the second light-receiving surface 212 of the second substrate 21, and the second coating layer 22 is applied to filter the external light received by the second light-receiving surface 212. According to the design and functional requirements of the second flip-chip photodiode unit 20, a material, a thickness and an area of the second coating layer 22 can be varied correspondingly.

In the present invention, the second flip-chip photodiode unit 20 is disposed adjacent to the first flip-chip photodiode unit 10. That is, one side surface of the first substrate 11 of the first flip-chip photodiode unit 10 abuts a corresponding side surface of the second substrate 21 of the second flip-chip photodiode unit 20. In the present invention, the first mounting surface 111 of the first substrate 11 of the first flip-chip photodiode unit 10 is coplanar with the second mounting surface 211 of the second substrate 21 of the second flip-chip photodiode unit 20, so as to facilitate arranging of corresponding electrodes and/or current guiding structures.

The first common electrode 30 is disposed at least on the first mounting surface 111 of the first substrate 11. That is, the first common electrode 30 can be disposed only on the first mounting surface 111 of the first substrate 11, or alternatively, can be extend across and be disposed on both the first mounting surface 111 of the first substrate 11 and the second mounting surface 211 of the second substrate 21. According to the different design and functional requirements of the flip-chip photodiode integrated structure 1 of the present invention, the electrode material of the first common electrode 30 can be varied correspondingly.

The second common electrode 40 is disposed at least on the second mounting surface 211 of the second substrate 21. That is, the second common electrode 40 can be disposed only on the second mounting surface 211 of the second substrate 21, or alternatively, can be extend across and be disposed on both the first mounting surface 111 of the first substrate 11 and the second mounting surface 211 of the second substrate 21. According to the different design and functional requirements of the flip-chip photodiode integrated structure 1 of the present invention, the electrode material of the second common electrode 40 can be varied correspondingly.

In the present embodiment, the first common electrode 30 is partially disposed on the first mounting surface 111 of the first substrate 11. Actually, the first common electrode 30 extends from the first mounting surface 111 straightly to the second mounting surface 211, by crossing lateral contacting sides of the first substrate 11 and of the second substrate 21, so that the first common electrode 30 contacts the first substrate 11 and the second substrate 21 concurrently. The second common electrode 40 is partially disposed on the second mounting surface 211 of the second substrate 21. Actually, the second common electrode 40 extends from the second mounting surface 211 straightly to the first mounting surface 111, by crossing the lateral contacting sides of the first substrate 11 and of the second substrate 21, so that the second common electrode 40 contacts the first substrate 11 and the second substrate 21 concurrently.

Accordingly, the flip-chip photodiode integrated structure 1 of the present embodiment is constructed with the first flip-chip photodiode unit 10 and the second flip-chip photodiode unit 20 collectively in a parallel connection design. Once the first common electrode 30 and the second common electrode 40 are electrically conducted, current flows from the first common electrode 30, simultaneously through the first substrate 11 and the second substrate 21, to the second common electrode 40 respectively, so as to make the first flip-chip photodiode unit 10 and the second flip-chip photodiode unit 20 operate independently and simultaneously.

In the present invention, the flip-chip photodiode integrated structure comprises a plurality of flip-chip photodiode units having different structural designs and characteristics. For example, in this embodiment, the first flip-chip photodiode unit 10 and the second flip-chip photodiode unit 20 are flip-chip photodiode units with different characteristics. Such as, according to the different designs and functional requirements of the first flip-chip photodiode unit 10 and the second flip-chip photodiode unit 20, at least one difference, existing between the first flip-chip photodiode unit 10 and the second flip-chip photodiode unit 20, is selected from a group consisting of substrate materials, substrate thicknesses, substrate areas, substrate doping concentrations, substrate doping depths, light-receiving surface coating materials, light-receiving surface coating thicknesses, light-receiving surface coating areas and common electrode materials.

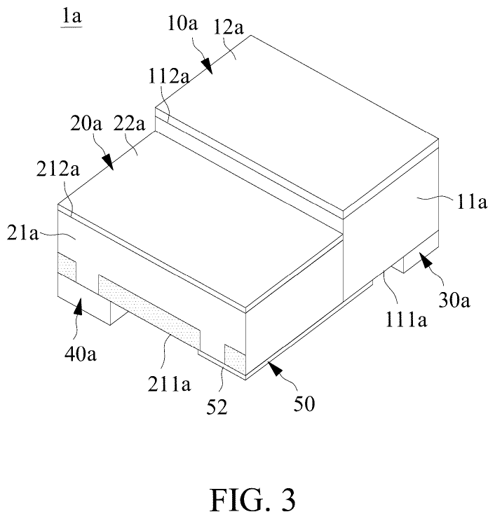

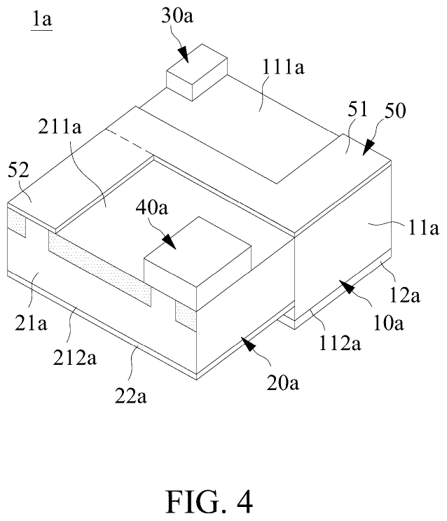

Please refer to FIG. 3 and FIG. 4 jointly, wherein FIG. 3 is a perspective view of a flip-chip photodiode integrated structure 1a of a second embodiment according to the present invention, and FIG. 4 is another perspective view of the flip-chip photodiode integrated structure 1a of the second embodiment according to the present invention. This embodiment is a variation of the aforementioned first embodiment, mainly differing in the arrangement of the first common electrode 30a and the second common electrode 40a, and further adding a metal connecting member 50. As shown in FIG. 3 and FIG. 4, in this embodiment, the first common electrode 30a of the flip-chip photodiode integrated structure 1a of the present invention is only disposed on the first mounting surface 111a of the first substrate 11a, and the second common electrode 40a is only disposed on the second mounting surface 211a of the second substrate 21a.

The flip-chip photodiode integrated structure 1a of the present embodiment further comprises a metal connecting member 50 to guide current from the first flip-chip photodiode unit 10a to the second flip-chip photodiode unit 20a. The metal connecting member 50 is disposed both on the first mounting surface 111a and the second mounting surface 211a, and the metal connecting member 50 extends from the first mounting surface 111a straightly to the second mounting surface 211a, by crossing lateral contacting sides of the first substrate 11a and of the second substrate 21a, so that the metal connecting member 50 contacts the first substrate 11a and the second substrate 21a concurrently. In this embodiment, the metal connecting member 50 includes a first end 51 and a second end 52. The first end 51 is disposed on the first mounting surface 111a and is located opposite to the first common electrode 30a relatively, so that the first end 51 is able to receive current from the first common electrode 30a flowing through the first substrate 11a. The second end 52 is disposed on the second mounting surface 211a and is located opposite to the second common electrode 40a relatively, so that the second end 52 is able to receive current from the first end 51 and then delivers the current to the second common electrode 40a through the second substrate 21a.

Accordingly, the flip-chip photodiode integrated structure 1a of the present embodiment is constructed with the first flip-chip photodiode unit 10a and the second flip-chip photodiode unit 20a collectively in a series connection design. Once the first common electrode 30a and the second common electrode 40a are electrically conducted, current flows from the first common electrode 30a, through the first substrate 11a, to the first end 51 of the metal connecting member 50 initially. Then, the metal connecting member 50 serves as a current conduction path for allowing the current to flow from the first end 51 to the second end 52. Next, the current flows from the second end 52 of the metal connecting member 50, through the second substrate 21a, to the second common electrode 40a. Thus, the first flip-chip photodiode unit 10a and the second flip-chip photodiode unit 20a are allowed to operate independently and simultaneously.

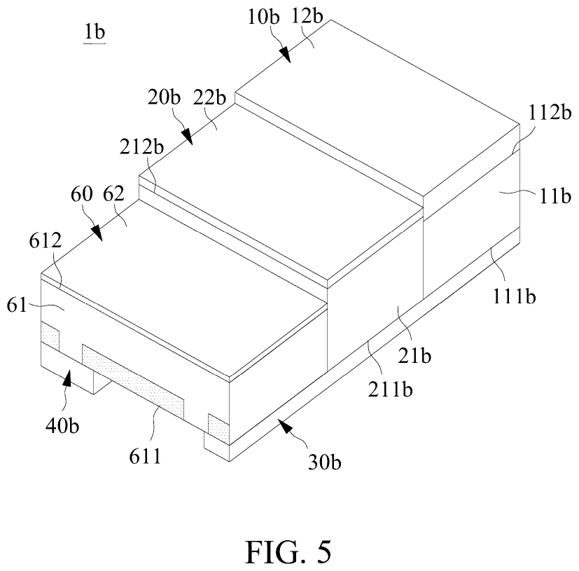

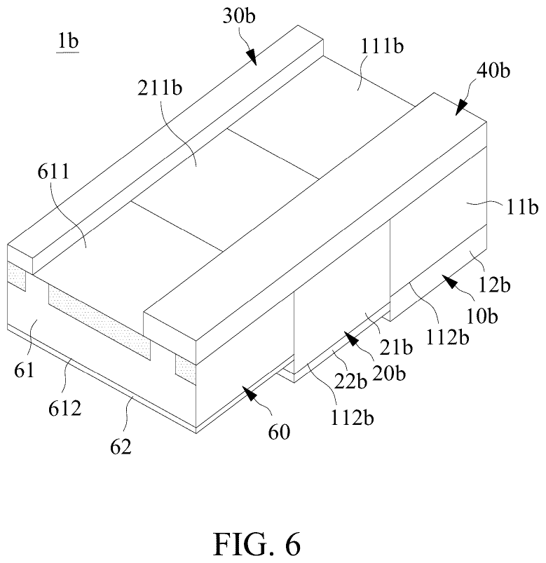

Please refer to FIG. 5 and FIG. 6 collectively, wherein FIG. 5 is a perspective view of a flip-chip photodiode integrated structure 1b of a third embodiment according to the present invention, and FIG. 6 is another perspective view of the flip-chip photodiode integrated structure 1b of the third embodiment according to the present invention. This embodiment is also a variation of the aforementioned first embodiment, mainly differing in the arrangement of the first common electrode 30b and the second common electrode 40b and further adding a third flip-chip photodiode unit 60. As shown in FIG. 5 and FIG. 6, in this embodiment, the flip-chip photodiode integrated structure 1b of the present invention further comprises the third flip-chip photodiode unit 60. The first flip-chip photodiode unit 10b, the second flip-chip photodiode unit 20b and the third flip-chip photodiode unit 60 are independent flip-chip photodiode units that can perform respective functions. The first common electrode 30b and the second common electrode 40b are electrodes shared by the first flip-chip photodiode unit 10b, the second flip-chip photodiode unit 20b and the third flip-chip photodiode unit 60.

The third flip-chip photodiode unit 60 includes a third substrate 61 and a third coating layer 62. The third substrate 61 is a fundamental structure component of the third flip-chip photodiode unit 60, and is mainly formed by semiconductor materials through epitaxial processing. According to different design and functional requirements of the third flip-chip photodiode unit 60, the material, a thickness, an area, a doping concentration and a doping depth of the third substrate 61 can be varied correspondingly. The third substrate 61 has a third mounting surface 611 and a third light-receiving surface 612 opposite each other. The third mounting surface 611 is configured for disposing corresponding electrodes or current guiding structures, and the third light-receiving surface 612 is configured to receive external light for performing photoelectric conversion of the third substrate 61.

The third coating layer 62 is disposed on the third light-receiving surface 612 of the third substrate 61, and the third coating layer 62 is applied to filter the external light received by the third light-receiving surface 612. According to the design and functional requirements of the third flip-chip photodiode unit 60, the material, a thickness and an area of the third coating layer 62 can be varied correspondingly.

In the present embodiment, the third flip-chip photodiode unit 60 is disposed adjacent to the second flip-chip photodiode unit 20b. That is, one side surface of the third substrate 61 of the third flip-chip photodiode unit 60 abuts a corresponding side surface of the second substrate 21b of the second flip-chip photodiode unit 20b. But the present invention is not limited thereto, the third flip-chip photodiode unit 60 can alternatively be disposed adjacent to the first flip-chip photodiode unit 10b. In this embodiment, the first mounting surface 111b of the first substrate 11b of the first flip-chip photodiode unit 10b, the second mounting surface 211b of the second substrate 21b of the second flip-chip photodiode unit 20b and the third mounting surface 611 of the third substrate 61 of the third flip-chip photodiode unit 60 are coplanar, so as to facilitate arranging of corresponding electrodes and/or current guiding structures.

In the present embodiment, the first common electrode 30b is partially disposed on the first mounting surface 111b of the first substrate 11b. Actually, the first common electrode 30b extends from the first mounting surface 111b straightly to the second mounting surface 211b, by crossing lateral contacting sides of the first substrate 11b and of the second substrate 21b, and further extends from the second mounting surface 211b straightly to the third mounting surface 611, by crossing lateral contacting sides of the second substrate 21b and of the third substrate 61, so that the first common electrode 30b contacts the first substrate 11b, the second substrate 21b and the third substrate 61 concurrently. The second common electrode 40b is partially disposed on the second mounting surface 211b of the second substrate 21b. Actually, one end of the second common electrode 40b extends from the second mounting surface 211b straightly to the first mounting surface 111b, by crossing lateral contacting sides of the first substrate 11b and of the second substrate 21b, while the other end of the second common electrode 40b extends from the second mounting surface 211b straightly to the third mounting surface 611, by crossing lateral contacting sides of the second substrate 21b and of the third substrate 61, so that the second common electrode 40b contacts the first substrate 11b, the second substrate 21b and the third substrate 61 concurrently.

Accordingly, the flip-chip photodiode integrated structure 1b of the present embodiment is constructed with the first flip-chip photodiode unit 10b, the second flip-chip photodiode unit 20b and the third flip-chip photodiode unit 60 collectively in a parallel connection design. Once the first common electrode 30b and the second common electrode 40b are electrically conducted, current flows from the first common electrode 30b to the second common electrode 40b, simultaneously and respectively through the first substrate 11b, the second substrate 21b and the third substrate 61, so that the first flip-chip photodiode unit 10b, the second flip-chip photodiode unit 20b and the third flip-chip photodiode unit 60 are allowed to operate independently and simultaneously.

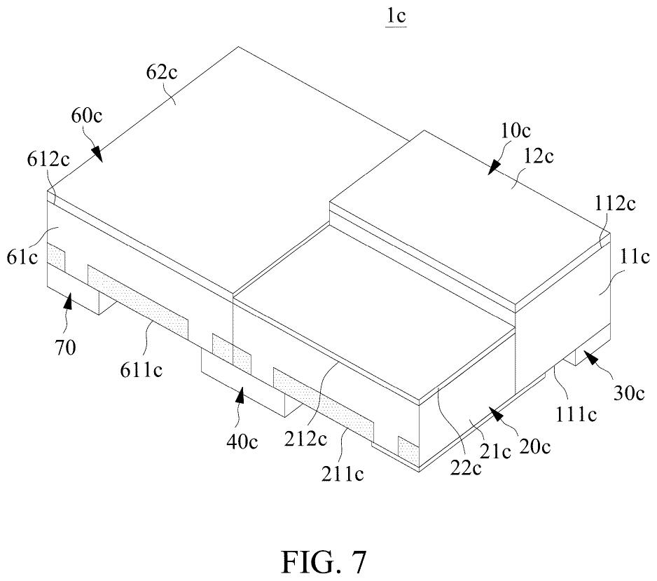

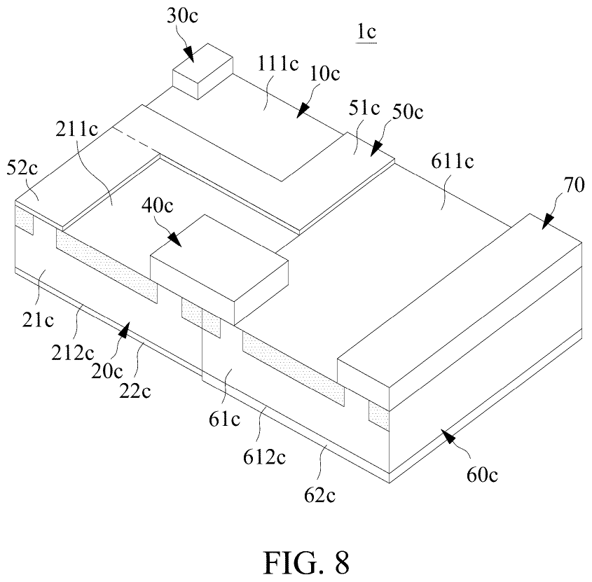

Please refer to FIG. 7 and FIG. 8 together, wherein FIG. 7 is a perspective view of a flip-chip photodiode integrated structure 1c of a fourth embodiment according to the present invention, and FIG. 8 is another perspective view of the flip-chip photodiode integrated structure 1c of the fourth embodiment according to the present invention. This embodiment is a variation of the aforementioned second embodiment, mainly differing in the arrangement of the second common electrode 40c, and further adding a third flip-chip photodiode unit 60c and a third common electrode 70. As shown in FIG. 7 and FIG. 8, in this embodiment, the flip-chip photodiode integrated structure 1c of the present invention further comprises the third flip-chip photodiode unit 60c. The first flip-chip photodiode unit 10c, the second flip-chip photodiode unit 20c and the third flip-chip photodiode unit 60c are independent flip-chip photodiode units that can perform respective functions. The first common electrode 30c, the second common electrode 40c and the third common electrode 70 are electrodes shared by the first flip-chip photodiode unit 10c, the second flip-chip photodiode unit 20c and the third flip-chip photodiode unit 60c. Since the third flip-chip photodiode unit 60c of this embodiment adopts the same structural design as the third flip-chip photodiode unit 60 of the aforementioned third embodiment, further detailed description thereof is omitted herein for brevity.

In the present embodiment, the third flip-chip photodiode unit 60c is disposed adjacent to the first flip-chip photodiode unit 10c and the second flip-chip photodiode unit 20c concurrently. That is, one side surface of the third substrate 61c of the third flip-chip photodiode unit 60c abuts a corresponding side surface of the first substrate 11c of the first flip-chip photodiode unit 10c and abuts a corresponding side surface of the second substrate 21c of the second flip-chip photodiode unit 20c. But this invention is not limited thereto, the third flip-chip photodiode unit 60c can be disposed only adjacent to the first flip-chip photodiode unit 10c or only adjacent to the second flip-chip photodiode unit 20c. In this embodiment, the first mounting surface 111c of the first substrate 11c of the first flip-chip photodiode unit 10c, the second mounting surface 211c of the second substrate 21c of the second flip-chip photodiode unit 20c and the third mounting surface 611c of the third substrate 61c of the third flip-chip photodiode unit 60c are coplanar, so as to facilitate arranging of corresponding electrodes and/or current guiding structures. The metal connecting member 50c is arranged on the first mounting surface 111c and the second mounting surface 211c, and the metal connecting member 50c extends from the first mounting surface 111c to the second mounting surface 211c, by crossing lateral contacting sides of the first substrate 11c and of the second substrate 21c, so that the metal connecting member 50c contacts the first substrate 11c and the second substrate 21c concurrently.

In the present embodiment, the first common electrode 30c is only disposed on the first mounting surface 111c of the first substrate 11c, and the third common electrode 70 is only disposed on the third mounting surface 611c of the third substrate 61c. The second common electrode 40c is partially disposed on the second mounting surface 211c of the second substrate 21c, and the second common electrode 40c extends from the second mounting surface 211c straightly to the third mounting surface 611c, by crossing lateral contacting sides of the second substrate 21c and of the third substrate 61c, so that the second common electrode 40c contacts the second substrate 21c and the third substrate 61c concurrently. According to the different design and functional requirements of the flip-chip photodiode integrated structure 1c of the present invention, the electrode material of the third common electrode 70 can be varied correspondingly.

Accordingly, the flip-chip photodiode integrated structure 1c of the present embodiment is constructed with the first flip-chip photodiode unit 10c and the second flip-chip photodiode unit 20c collectively in a parallel connection design, and this parallel connection design emerges with the aforementioned third flip-chip photodiode unit 60c to collectively form a series connection design. Once the first common electrode 30c, the second common electrode 40c and the third common electrode 70 are electrically conducted, the current flows from the first common electrode 30c, through the first substrate 11c, to the first end 51c of the metal connecting member 50c initially, and then the current flows from the second end 52c of the metal connecting member 50c, through the second substrate 21c, to the second common electrode 40c. While simultaneously, the current flows from the third common electrode 70, through the third substrate 61c, to the second common electrode 40c. Thus, the first flip-chip photodiode unit 10c, the second flip-chip photodiode unit 20c and the third flip-chip photodiode unit 60c are allowed to operate independently and simultaneously.

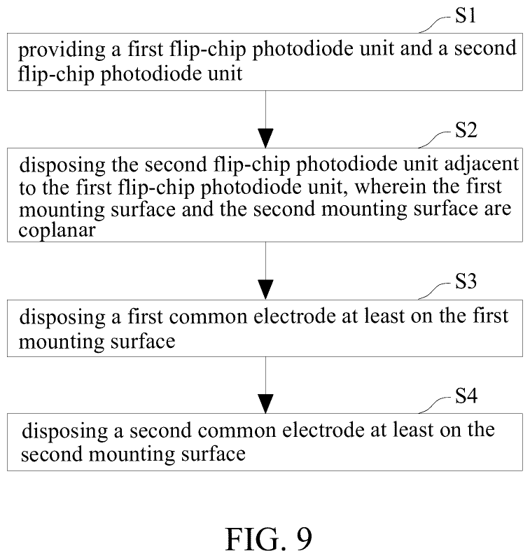

Please refer to FIG. 1, FIG. 2 and FIG. 9, wherein FIG. 9 is a flowchart of a manufacturing method of the flip-chip photodiode integrated structure according to the present invention. The manufacturing method of the flip-chip photodiode integrated structure of the present invention is described below by taking the aforementioned first embodiment of the flip-chip photodiode integrated structure 1 as an example. As shown in FIG. 1, FIG. 2 and FIG. 9, the manufacturing method of the flip-chip photodiode integrated structure of the present invention comprises steps disclosed below:
Step S1: providing a first flip-chip photodiode unit 10 and a second flip-chip photodiode unit 20.

First, the present invention provides a first flip-chip photodiode unit 10 and a second flip-chip photodiode unit 20. Wherein the first flip-chip photodiode unit 10 includes a first substrate 11, and the first substrate 11 has a first mounting surface 111 and a first light-receiving surface 112 opposite each other. The second flip-chip photodiode unit 20 includes a second substrate 21, and the second substrate 21 has a second mounting surface 211 and a second light-receiving surface 212 opposite each other.

Step S2: disposing the second flip-chip photodiode unit 20 adjacent to the first flip-chip photodiode unit 10, wherein the first mounting surface 111 and the second mounting surface 211 are coplanar.

After the first flip-chip photodiode unit 10 and the second flip-chip photodiode unit 20 are provided in Step S1, one side surface of the first substrate 11 of the first flip-chip photodiode unit 10 is disposed adjacent to a corresponding side surface of the second substrate 21 of the second flip-chip photodiode unit 20 for the present invention. Meanwhile, the first mounting surface 111 of the first substrate 11 and the second mounting surface 211 of the second substrate 21 are kept coplanar.

Step S3: disposing a first common electrode 30 at least on the first mounting surface 111.

After the second flip-chip photodiode unit 20 and the first flip-chip photodiode unit 10 are adjacently disposed in Step S2, a first common electrode 30 is then disposed at least on the first mounting surface 111 of the first substrate 11 for the present invention. Taking the first embodiment of the aforementioned flip-chip photodiode integrated structure 1 as an example, as shown in FIG. 1 and FIG. 2, the first common electrode 30 extends straightly from the first mounting surface 111 to the second mounting surface 211, so that the first common electrode 30 contacts the first substrate 11 and the second substrate 21 concurrently, but not limited thereto for the present invention.

Step S4: disposing a second common electrode 40 at least on the second mounting surface 211.

After the first common electrode 30 is disposed in Step S3, a second common electrode 40 is disposed at least on the second mounting surface 211 of the second substrate 21 for the present invention. In one embodiment of the present invention, the second common electrode 40 extends from the second mounting surface 211 to the first mounting surface 111, so that the second common electrode 40 contacts the first substrate 11 and the second substrate 21 concurrently, but not limited thereto for the present invention.

Accordingly, the flip-chip photodiode integrated structure 1 fabricated by the aforementioned manufacturing method is constructed with the first flip-chip photodiode unit 10 and the second flip-chip photodiode unit 20 collectively in a parallel connection design. By electrically conducting the first common electrode 30 and the second common electrode 40, the first flip-chip photodiode unit 10 and the second flip-chip photodiode unit 20 of the flip-chip photodiode integrated structure 1 are allowed to operate independently and simultaneously.

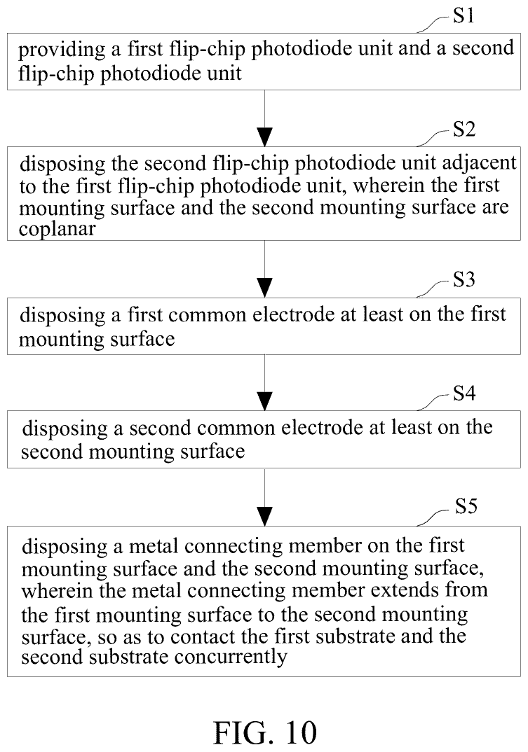

Please refer to FIG. 3, FIG. 4 and FIG. 10, wherein FIG. 10 is a flowchart of the manufacturing method of another embodiment of the flip-chip photodiode integrated structure according to the present invention. The manufacturing method of the flip-chip photodiode integrated structure of the present invention is described below by taking the aforementioned second embodiment of the flip-chip photodiode integrated structure 1a as an example. As shown in FIG. 3, FIG. 4 and FIG. 10, the manufacturing method of the flip-chip photodiode integrated structure of the present invention further comprises Step S5: disposing a metal connecting member 50 on the first mounting surface 111a and the second mounting surface 211a, wherein the metal connecting member 50 extends from the first mounting surface 111a to the second mounting surface 211a, so as to contact the first substrate 11a and the second substrate 21a concurrently.

Taking the aforementioned second embodiment of the flip-chip photodiode integrated structure 1a as an example, as illustrated in FIG. 3 and FIG. 4, the first common electrode 30a is only disposed on the first mounting surface 111a of the first substrate 11a in Step S3, and the second common electrode 40a is only disposed on the second mounting surface 211a of the second substrate 21a in Step S4. After the first common electrode 30a and the second common electrode 40a are disposed in Step S3 and Step S4, a metal connecting member 50 is disposed on the first mounting surface 111a of the first substrate 11a and the second mounting surface 211a of the second substrate 21a for the present invention. Meanwhile, the metal connecting member 50 extends from the first mounting surface 111a to the second mounting surface 211a to contact the first substrate 11a and the second substrate 21a concurrently.

Accordingly, the flip-chip photodiode integrated structure 1a fabricated by the aforementioned manufacturing method is constructed with the first flip-chip photodiode unit 10a and the second flip-chip photodiode unit 20a collectively in a series connection design. By electrically conducting the first common electrode 30a and the second common electrode 40a, the first flip-chip photodiode unit 10a and the second flip-chip photodiode unit 20a of the flip-chip photodiode integrated structure 1a are allowed to operate independently and simultaneously.

As mentioned above, the flip-chip photodiode integrated structure of the present invention combines multiple flip-chip photodiode units of different types or characteristics within the same flip-chip structure, so that the flip-chip photodiode integrated structure of the present invention is able to simultaneously drive the flip-chip photodiode units of different characteristics or functions to operate after being electrically conducted, thus forming a multifunctional flip-chip photodiode integrated structure. Furthermore, the flip-chip photodiode integrated structure of the present invention can effectively reduce the packaging area and simplify the complex wire bonding process, thereby reducing manufacturing costs.

The above implementations are only auxiliary descriptions, and are not intended to limit the embodiments of the application subject or the applications or uses of the embodiments. In addition, although at least one illustrative example has been presented above, it should be understood that the present invention can still have a large quantity of variations. It should also be understood that the embodiments described herein are not intended to limit the scope, use, or configuration of the requested subject matter in any way. On the contrary, the foregoing embodiments will provide a convenient guide for those skilled in the art to implement one or more embodiments. Furthermore, various changes can be made to the function and arrangement of the components without departing from the scope defined by the patent claims, and the scope of the patent claims includes known equivalents and all foreseeable equivalents at the time that the patent application is filed.

What is claimed is:

1. A flip-chip photodiode integrated structure, comprising:
a first flip-chip photodiode unit, including a first substrate, wherein the first substrate has a first mounting surface and a first light-receiving surface opposite each other;
a second flip-chip photodiode unit, including a second substrate, wherein the second substrate has a second mounting surface and a second light-receiving surface opposite each other, and wherein the second flip-chip photodiode unit is disposed adjacent to the first flip-chip photodiode unit, and the first mounting surface is coplanar with the second mounting surface;
a first common electrode, disposed at least on the first mounting surface; and
a second common electrode, disposed at least on the second mounting surface, wherein the first flip-chip photodiode unit and the second flip-chip photodiode unit are allowed to operate independently and simultaneously by electrically conducting the first common electrode and the second common electrode.

2. The flip-chip photodiode integrated structure as claimed in claim 1, wherein the first common electrode extends from the first mounting surface to the second mounting surface, so as to contact the first substrate and the second substrate concurrently, and wherein the second common electrode extends from the second mounting surface to the first mounting surface, so as to contact the first substrate and the second substrate concurrently.

3. The flip-chip photodiode integrated structure as claimed in claim 1, further comprising a metal connecting member, wherein the metal connecting member extends from the first mounting surface to the second mounting surface, so as to contact the first substrate and the second substrate concurrently.

4. The flip-chip photodiode integrated structure as claimed in claim 3, wherein the metal connecting member includes a first end and a second end, wherein the first end is disposed on the first mounting surface and located at one side opposite to the first common electrode, to receive current from the first common electrode and flowing through the first substrate, and wherein the second end is disposed on the second mounting surface and located at one side opposite to the second common electrode, to let the current from the first end flow to the second common electrode through the second substrate.

5. The flip-chip photodiode integrated structure as claimed in claim 1, wherein the first flip-chip photodiode unit and the second flip-chip photodiode unit are flip-chip photodiode units having different characteristics respectively.

6. The flip-chip photodiode integrated structure as claimed in claim 5, wherein at least one difference existed between the first flip-chip photodiode unit and the second flip-chip photodiode unit, is selected from the group consisting of substrate materials, substrate thicknesses, substrate areas, substrate doping concentrations, substrate doping depths, light-receiving surface coating materials, light-receiving surface coating thicknesses, light-receiving surface coating areas and common electrode materials.

7. The flip-chip photodiode integrated structure as claimed in claim 1, further comprising:
a third flip-chip photodiode unit, including a third substrate, wherein the third substrate has a third mounting surface and a third light-receiving surface opposite each other, wherein the third flip-chip photodiode unit is disposed adjacent to the first flip-chip photodiode unit or the second flip-chip photodiode unit, and wherein the first mounting surface, the second mounting surface and the third mounting surface are coplanar;
wherein the first common electrode extends from the first mounting surface to the second mounting surface and to the third mounting surface, so that the first common electrode contacts the first substrate, the second substrate and the third substrate concurrently, and wherein the second common electrode extends from the second mounting surface to the first mounting surface and to the third mounting surface, so that the second common electrode contacts the first substrate, the second substrate and the third substrate concurrently; and
wherein the first flip-chip photodiode unit, the second flip-chip photodiode unit and the third flip-chip photodiode unit are allowed to operate independently and simultaneously by electrically conducting the first common electrode and the second common electrode.

8. The flip-chip photodiode integrated structure as claimed in claim 1, further comprising:
a third flip-chip photodiode unit, including a third substrate, wherein the third substrate has a third mounting surface and a third light-receiving surface opposite each other, wherein the third flip-chip photodiode unit is disposed adjacent to the first flip-chip photodiode unit and/or the second flip-chip photodiode unit, and wherein the first mounting surface, the second mounting surface and the third mounting surface are coplanar;
a metal connecting member, extending from the first mounting surface to the second mounting surface, so as to contact the first substrate and the second substrate concurrently; and
a third common electrode, disposed at least on the third mounting surface, wherein the first flip-chip photodiode unit, the second flip-chip photodiode unit and the third flip-chip photodiode unit are allowed to operate independently and simultaneously by electrically conducting the first common electrode, the second common electrode and the third common electrode.

9. The flip-chip photodiode integrated structure as claimed in claim 8, wherein the second common electrode extends from the second mounting surface to the third mounting surface, so as to contact the second substrate and the third substrate concurrently.

10. A manufacturing method of a flip-chip photodiode integrated structure, comprising following steps:
providing a first flip-chip photodiode unit and a second flip-chip photodiode unit, wherein the first flip-chip photodiode unit includes a first substrate, and the first substrate has a first mounting surface and a first light-receiving surface opposite each other, and wherein the second flip-chip photodiode unit includes a second substrate, and the second substrate has a second mounting surface and a second light-receiving surface opposite each other;
disposing the second flip-chip photodiode unit adjacent to the first flip-chip photodiode unit, wherein the first mounting surface and the second mounting surface are coplanar;
disposing a first common electrode at least on the first mounting surface, and
disposing a second common electrode at least on the second mounting surface;
wherein the first flip-chip photodiode unit and the second flip-chip photodiode unit are allowed to operate independently and simultaneously by electrically conducting the first common electrode and the second common electrode.

11. The manufacturing method of the flip-chip photodiode integrated structure as claimed in claim 10, wherein the first common electrode extends from the first mounting surface to the second mounting surface, so as to contact the first substrate and the second substrate concurrently, and wherein the second common electrode extends from the second mounting surface to the first mounting surface, so as to contact the first substrate and the second substrate concurrently.

12. The manufacturing method of the flip-chip photodiode integrated structure as claimed in claim 10, further comprising following step:
disposing a metal connecting member on the first mounting surface and the second mounting surface, wherein the metal connecting member extends from the first mounting surface to the second mounting surface, so as to contact the first substrate and the second substrate concurrently.
